(19) United States
(12) Patent Application Publication
(10) Pub. No.: US 2023/0055735 A1
(43) Pub. Date: Feb. 23, 2023

(54) ETCHANT FOR ETCHING TRIPLE LAYER METAL WIRING STRUCTURES OF MOLYBDENUM/COPPER/MOLYBDENUM OR MOLYBDENUM ALLOY/COPPER/MOLYBDENUM, AND APPLICATION THEREOF

(71) Applicant: TCL CHINA STAR OPTOELECTRONICS TECHNOLOGY CO., LTD., Shenzhen (CN)

(72) Inventor: Jing Liu, Shenzhen (CN)

(73) Assignee: TCL CHINA STAR OPTOELECTRONICS TECHNOLOGY CO., LTD., Shenzhen (CN)

(21) Appl. No.: 17/053,626

(22) PCT Filed: Sep. 24, 2020
(86) PCT No.: PCT/CN2020/117280

§ 371 Date: Nov. 6, 2020

(30) Foreign Application Priority Data
Sep. 2, 2020 (CN) 202010908831.4

(51) Int. Cl. C23F 1/44; C23F 1/18; C23F 1/26

(52) U.S. Cl. CPC C23F 1/44; C23F 1/18; C23F 1/26

(57) ABSTRACT

An etchant composition for etching a triple layer metal wiring structure of molybdenum/copper/molybdenum or molybdenum alloy/copper/molybdenum alloy, and a use thereof are disclosed. The etchant composition includes hydrogen peroxide, glycol, an etching inhibitor, a chelating agent, an etching additive, a pH adjuster, and water, The etchant can not only slow down the decomposition of hydrogen peroxide, but also extend the lifespan of the etchant, thereby greatly reducing the costs of the etchant in the manufacturing process, and improving the safety factor of the etchant.

### FIELD OF INVENTION

The present disclosure relates to semiconductor metal wiring technology, especially relates to metal wiring etching technology, and more specifically relates to an etchant composition for etching a triple layer metal wiring structure of molybdenum/copper/molybdenum or molybdenum alloy/copper/molybdenum alloy, and application thereof.

### BACKGROUND OF INVENTION

Processes of forming metal wiring on semiconductor array substrate usually includes: a sputter film forming process, a resist or photoresist coating and development process, a wet etching process for forming the metal wiring, and a stripping process of the resist or photoresist after patterning of the metal wiring for removal of unwanted resist or photoresist.

Requirements of different metal wiring upper-lower layer structures, and different array substrate manufacturing process for etching characteristics of etchant are different. When a layer below the metal wiring is an oxide semiconductor active layer, the wet etching of the metal wiring not only needs to maintain superior etching characteristics, but also needs to minimize an etching effect that the etchant applies to the oxide semiconductor, thereby maintaining superior electrical structure of the active layer, and thereby ensuring reliability of panels. Therefore, etchant systems based on the oxide semiconductor are usually fluorine-free etchant systems.

Present source electrodes and drain electrodes based on oxide semiconductor technology are usually triple layer metal structures, including metal laminated structures of molybdenum/copper/molybdenum or molybdenum alloy/copper/molybdenum alloy. In the fluorine-free etchant systems, the only way to meet the requirements of one-step wet etching of the three layer metal structure is to increase hydrogen peroxide content in the etchant to 20-30 wt %. However, because the hydrogen peroxide content is relatively high, hydrogen peroxide in the etchant is unstable, and a concentration of the hydrogen peroxide in the etchant drops fast during the etching process. As a result, even when copper ion concentration in the etchant is relatively low (about 2000 ppm), uniformity and stability of the etching process cannot be maintained, which leads to great reduction of a lifespan of the etchant (That is, when the copper ion concentration of the present batch reaches about 2000 ppm, the present batch of the etchant can no longer be used and needs to be replaced with a new batch of the etchant). The maximum copper ion concentration contained in the etchant while the etchant may still ensure the uniformity and stability of the etching process is referred to as the lifespan of the etchant.

### SUMMARY OF INVENTION

### Technical Problem

The present disclosure provides an etchant composition for etching metal wiring structure of molybdenum/copper/molybdenum (or molybdenum alloy/copper/molybdenum alloy). The hydrogen peroxide in the etchant is stable, and the lifespan of the etchant is extended. The etchant may be effectively applied in the etching process of the metal wiring.

### Technical Solution

The embodiments of the present disclosure provide an etchant composition for etching a metal wiring structure of molybdenum/copper/molybdenum (or molybdenum alloy/copper/molybdenum alloy), wherein the etchant composition comprises: hydrogen peroxide, glycol, an etching inhibitor, a chelating agent, an etching additive, a pH adjuster, and water;

wherein the glycol is at least one selected from ethylene glycol, propylene glycol, diethylene glycol, propane-1,2-diol, triethylene glycol, 1,2-propanediol, 1,3-propanediol, 1,4-butanediol, 1,5-pentanediol, 1,6-hexanediol, 1,7-heptandiol, 1,8-octanediol, 1,9-nonanediol, 1,10-decanediol, cyclopentane-1,2-diol, and cyclohexane-1,4-diol.

In the etchant composition, the etchant composition comprises: 20-30 wt % of hydrogen peroxide, 0.1-10 wt % of glycol, 0.1-5 wt % of the etching inhibitor, 0.1-5 wt % of the chelating agent, 0.1-5 wt % of the etching additive, 0.1-3 wt % of the pH adjuster, and the remainder being water.

In the etchant composition, a pH value of the etchant composition ranges from 2 to 6.

In the etchant composition, the etchant composition comprises: 23-27 wt % of hydrogen peroxide, 2-8 wt % of glycol, 1-3 wt % of the etching inhibitor, 1-4 wt % of the chelating agent, 1-3 wt % of the etching additive, 0.8-2 wt % of the pH adjuster, and the remainder being water.

In the etchant composition, the pH value of the etchant composition is maintained in a range of from 3 to 6.

In the etchant composition, the pH adjuster is at least one selected from organic bases, inorganic bases, and basic salts.

In the etchant composition, the etching inhibitor is a C1-C10 heterocyclic compound.

In the etchant composition, hetero atoms contained in the heterocyclic compound are at least one selected from O, S, and N.

In the etchant composition, the chelating agent is a compound containing amino group and carboxyl group.

In the etchant composition, the chelating agent is at least one selected from iminodiacetic acid, nitrilotriacetic acid, ethylenediaminetetraacetic acid, diethylenetriaminepentaacetic acid, nitrilotrimethylene triphosphonic acid, 1-hydroxyethylene-1,1-diphosphoric acid, ethylenediamine tetramethylene phosphoric acid, and diethylenetriamine penta(methylene phosphonic acid).

In the etchant composition, the etching additive is at least one selected from organic acids, inorganic acids, and phosphates.

In the etchant composition, the phosphate is at least one selected from monoammonium phosphate, diammonium phosphate, triammonium phosphate, sodium hydrogen phosphate, disodium hydrogen phosphate, sodium phosphate, potassium hydrogen phosphate, dipotassium hydrogen phosphate, and potassium phosphate.

The embodiments of the present disclosure also provide a use of the etchant composition in etching of a metal wiring structure, wherein the metal wiring structure is a triple layer metal wiring structure of molybdenum/copper/molybdenum laminated layers or molybdenum alloy/copper/molybdenum alloy laminated layers.

In the use, in the metal wiring, a thickness of a lowermost layer (first layer) ranges from 50 Å to 500 Å, a thickness of a middle copper electrode (second layer) ranges from 3000 Å to 10000 Å, and a thickness of an uppermost layer (third layer) ranges from 50 Å to 300 Å. The first layer and the third layer are metal blocking layers.

In the use, the etchant composition comprises: 20-30 wt % of hydrogen peroxide, 0.1-10 wt % of glycol, 0.1-5 wt % of an etching inhibitor, 0.1-5 wt % of a chelating agent, 0.1-5 wt % of an etching additive, 0.1-3 wt % of a pH adjuster, and the remainder being water.

In the use, a pH value of the etchant composition ranges from 2 to 6.

In the use, the pH adjuster is at least one selected from organic bases, inorganic bases, and basic salts; the etching inhibitor is a C1-C10 heterocyclic compound; the hetero atoms contained in the heterocyclic compound are at least one of O, S, or N; the chelating agent is a compound containing amino group and carboxyl group; and the etching additive is at least one selected from organic acids, inorganic acids, and phosphates.

The embodiments of the present disclosure also provide a method of manufacturing a thin film array substrate using the etchant composition, wherein the method comprises steps of:

forming a gate electrode having two layers of metal structures on a substrate;

forming a gate electrode insulating layer on the gate electrode;

forming an active layer of oxide semiconductor on the gate electrode insulating layer;

forming a source electrode and a drain electrode on the active layer, wherein each of the source electrode and the drain electrode is a triple layer metal structure, wherein the triple layer metal structure is molybdenum/copper/molybdenum laminated layers or molybdenum alloy/copper/molybdenum alloy laminated layers, wherein a thickness of a lowermost layer (first layer) ranges from 50 Å to 500 Å, a thickness of a middle copper electrode (second layer) ranges from 3000 Å to 10000 Å, and a thickness of an upper most layer (third layer) ranges from 50 Å to 300 Å; and

wet etching the source electrode and the drain electrode at a same time using the etchant composition.

In the method, the etchant composition comprises: 20-30 wt % of hydrogen peroxide, 0.1-10 wt % of glycol, 0.1-5 wt % of an etching inhibitor, 0.1-5 wt % of a chelating agent, 0.1-5 wt % of an etching additive, 0.1-3 wt % of a pH adjuster, and the remainder being water; and a pH value of the etchant composition ranges from 2 to 6.

In the method, the pH adjuster is at least one selected from organic bases, inorganic bases, and basic salts; the etching inhibitor is a C1-C10 heterocyclic compound; the hetero atoms contained in the heterocyclic compound are at least one of O, S, or N; the chelating agent is a compound containing amino group and carboxyl group; and the etching additive is at least one selected from organic acids, inorganic acids, and phosphates.

In the present disclosure, the gate electrode, the gate electrode insulating layer, the active layer, the source electrode, and the drain electrode in the method of manufacturing a thin film array substrate may be obtained by conventional method in the art.

In the present disclosure, the steps of the wet etching process may be selected from conventional steps in the art according to actual conditions.

By adding glycol additives to the etchant, the present disclosure not only stabilizes the hydrogen peroxide in the etchant, slowing down the degradation of the hydrogen peroxide (by combing with Cu²⁺, thereby preventing the degradation of the hydrogen peroxide), but also extends the life span of the etchant to 3000-4000 ppm, thereby greatly reducing the costs of the etchant in the manufacturing process, and improving the safety factor of the etchant.

If monohydric alcohols and trihydric alcohols are added to the etchant, the etching characteristics of the etchant will be changed.

Unless otherwise dictated, all materials used in the present disclosure may be commercial products.

Beneficial Effects:

Compared to the prior art, in the etchant composition for etching the triple layer metal wiring structure of molybdenum/copper/molybdenum or molybdenum alloy/copper/molybdenum alloy, and use thereof provided by the present disclosure, the etchant composition comprises constituents, such as hydrogen peroxide, glycol, etching inhibitor, chelating agent, etching additive, and pH adjuster. The constituents are used in combination by reasonable matching and scientific proportioning, thereby making the etchant of the present disclosure stable, and thereby extending the lifespan of the etchant, making the etchant effectively applied to the etching of the metal wiring.

Adding glycol to the etchant composition of the present disclosure for cooperating with other constituents can not only stabilize the hydrogen peroxide in the etchant, thereby slowing down the degradation of the hydrogen peroxide (by combing with Cu²⁺, thereby preventing the degradation of the hydrogen peroxide), but also extend the lifespan of the etchant to 3000-4000 ppm, thereby greatly reducing the costs of the etchant in the manufacturing process, and improving the safety factor of the etchant.

### DETAILED DESCRIPTION OF PREFERRED EMBODIMENTS

The present disclosure provides an etchant composition for etching a triple layer metal wiring structure of molybdenum/copper/molybdenum or molybdenum alloy/copper/molybdenum alloy. To make the objects, technical solutions, and beneficial effects of the present invention clearly understood, the present invention is described in detail below by reference to the embodiments hereinbelow. It should be understood that the specific embodiments described herein are merely to illustrate the invention, and are not intended to limit the present invention. It should be noted that, the terms “comprises”, “comprising”, “includes”, “including”, “having” and their conjugates mean “including but not limited to”. The terms such as “first”, “second”, and “third” are merely used as labels and do not imply numeral requirement or establish order. Throughout this application, various embodiments of this invention may be presented in a range format; it should be understood that the description in range format is merely for convenience and brevity and should not be construed as an inflexible limitation on the scope of the invention. Accordingly, the description of a range should be considered to have specifically disclosed all the possible sub ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range. In addition, whenever a numerical range is indicated herein, it is meant to include any cited numeral (fractional or integral) within the indicated range. The dimension and values disclosed in the present disclosure should not be construed as been strictly limited to the precise value. Conversely, unless otherwise indicated, the various values are meat to represent the cited numeral and the range which is the functionally equivalent of the cited numeral. For example, the disclosed dimension “10 microns” means “about 10 microns”.

An etchant composition for etching a triple layer metal wiring structure of molybdenum/copper/molybdenum or molybdenum alloy/copper/molybdenum alloy is provided by the present disclosure, wherein the etchant composition comprises: hydrogen peroxide, glycol, an etching inhibitor, a chelating agent, an etching additive, a pH adjuster, and water.

Wherein the glycol is at least one selected from ethylene glycol, propylene glycol, diethylene glycol, propane-1,2-diol, triethylene glycol, 1,2-propanediol, 1,3-propanediol, 1,4-butanediol, 1,5-pentanediol, 1,6-hexanediol, 1,7-heptandiol, 1,8-octanediol, 1,9-nonanediol, 1,10-decanediol, cyclopentane-1,2-diol, and cyclohexane-1,4-diol.

In some embodiments, a pH value of the etchant composition ranges from 2 to 6. For example, the pH value of the etchant composition may be 2, 3, 4, 5, or 6.

In some embodiments, the hydrogen peroxide is 20-30 wt % of the etchant composition. For example, the hydrogen peroxide may be 20%, 21%, 22%, 23%, 24%, 25%, 26%, 27%, 28%, 29%, or 30%.

In some embodiments, the glycol is 0.1-10 wt % of the etchant composition. For example, the glycol may be 0.1%, 0.3%, 0.5%, 0.8%, 1%, 2%, 4%, 6%, 8%, or 10%.

In some embodiments, the etching inhibitor is 0.1-5 wt % of the etchant composition. For example, the etching inhibitor may be 0.1%, 0.3%, 0.5%, 0.8%, 1%, 2%, 3%, 4%, or 5%.

In some embodiments, the chelating agent is 0.1-5 wt % of the etchant composition. For example, the chelating agent may be 0.1%, 0.3%, 0.5%, 0.8%, 1%, 2%, 3%, 4%, or 5%.

In some embodiments, the etching additive is 0.1-5 wt % of the etchant composition. For example, the etching additive may be 0.1%, 0.3%, 0.5%, 0.8%, 1%, 2%, 3%, 4%, or 5%.

In some embodiments, the pH adjuster is 0.1-3 wt % of the etchant composition. For example, the pH adjuster may be 0.1%, 0.3%, 0.5%, 0.8%, 1%, 1.5%, 2%, 2.5%, or 3%.

In some embodiments, the pH adjuster may be at least one selected from organic bases, inorganic bases, and basic salts.

In some embodiments, the etching inhibitor is a C1-C10 heterocyclic compound. The hetero atoms contained in the heterocyclic compound may be at least one selected from O, S, and N.

In some embodiments, the chelating agent is a compound containing amino group and carboxyl group. For example, the chelating agent may be at least one selected from iminodiacetic acid, nitrilotri acetic acid, ethylenediaminetetraacetic acid, diethylenetriaminepentaacetic acid, nitrilotrimethylene triphosphonic acid, 1-hydroxyethylene-1,1-diphosphoric acid, ethylenediamine tetramethylene phosphoric acid, and diethylenetriamine penta(methylene phosphonic acid).

In some embodiments, the etching additive is at least one selected from organic acids, inorganic acids, and phosphates. Wherein, the phosphate is at least one selected from monoammonium phosphate, diammonium phosphate, triammonium phosphate, sodium hydrogen phosphate, disodium hydrogen phosphate, sodium phosphate, potassium hydrogen phosphate, dipotassium hydrogen phosphate, and potassium phosphate.

Based on the aforementioned etchant composition, the present disclosure also correspondingly provides a use of the aforementioned etchant composition in etching of a metal wiring structure, wherein the metal wiring structure is a triple layer metal wiring structure of molybdenum/copper/molybdenum laminated layers or molybdenum alloy/copper/molybdenum alloy laminated layers.

In some embodiments, in the metal wiring, a thickness of a lowermost layer (first layer) ranges from 50 Å to 500 Å, a thickness of a middle copper electrode (second layer) ranges from 3000 Å to 10000 Å, and a thickness of an uppermost layer (third layer) ranges from 50 Å to 300 Å. The first layer and the third layer are metal blocking layers.

Based on the aforementioned etchant composition, the present disclosure also correspondingly provides a method of manufacturing a thin film array substrate using the aforementioned etchant composition, wherein the method comprises steps of:

forming a gate electrode having two layers of metal structures on a substrate;

forming a gate electrode insulating layer on the gate electrode;

forming an active layer of oxide semiconductor on the gate electrode insulating layer;

forming a source electrode and a drain electrode on the active layer, wherein each of the source electrode and the drain electrode is a triple layer metal structure, wherein the triple layer metal structure is molybdenum/copper/molybdenum laminated layers or molybdenum alloy/copper/molybdenum alloy laminated layers, wherein a thickness of a lowermost layer (first layer) ranges from 50 Å to 500 Å, a thickness of a middle copper electrode (second layer) ranges from 3000 Å to 10000 Å, and a thickness of an uppermost layer (third layer) ranges from 50 Å to 300 Å; and

wet etching the source electrode and the drain electrode at a same time using the etchant composition.

### Embodiment 1

The present embodiment provides an etchant composition comprising: 30 wt % of hydrogen peroxide, 10 wt % of glycol, 0.1 wt % of an etching inhibitor, 5 wt % of a chelating agent, 0.1 wt % of an etching additive, 3 wt % of a pH adjuster, and the remainder being water.

Wherein the glycol is ethylene glycol, diethylene glycol, or triethylene glycol.

Wherein a pH value of the etchant composition is maintained in a range of from 2 to 6.

Wherein the pH adjuster is an organic base.

Wherein the etching inhibitor is a C1-C10 heterocyclic compound. The hetero atoms contained in the heterocyclic compound are 0.

Wherein the chelating agent are compounds containing amino group and carboxyl group. The chelating agent is iminodiacetic acid, nitrilotriacetic acid, or ethylenediaminetetraacetic acid.

Wherein the etching additive is an organic acid.

### Embodiment 2

The present embodiment provides an etchant composition comprising: 20 wt % of hydrogen peroxide, 0.1 wt % of glycol, 5 wt % of an etching inhibitor, 0.1 wt % of a chelating agent, 5 wt % of an etching additive, 0.1 wt % of a pH adjuster, and the remainder being water.

Wherein the glycol is propylene glycol, propane-1,2-diol, 1,8-octanediol, or cyclopentane-1,2-diol.

Wherein a pH value of the etchant composition is maintained in a range of from 3 to 5.

Wherein the pH adjuster is an inorganic base or a basic salt.

Wherein the etching inhibitor is a C1-C10 heterocyclic compound. The hetero atoms contained in the heterocyclic compound are S or N.

Wherein the chelating agent is a compound containing amino group and carboxyl group. The chelating agent is diethylenetriaminepentaacetic acid, nitrilotrimethylene triphosphonic acid, or 1-hydroxyethylene-1,1-diphosphoric acid.

Wherein the etching additive is an inorganic acid or a phosphate. The phosphate is diammonium phosphate, sodium hydrogen phosphate, or sodium phosphate.

### Embodiment 3

The present embodiment provides an etchant composition comprising: 25 wt % of hydrogen peroxide, 5.5 wt % of glycol, 2.5 wt % of an etching inhibitor, 3 wt % of a chelating agent, 2.5 wt % of an etching additive, 1.5 wt % of a pH adjuster, and the remainder being water.

Wherein the glycol is ethylene glycol, 1,2-propanediol, 1,4-butanediol, or cyclohexane-1,4-diol.

Wherein a pH value of the etchant composition is maintained in a range of from 3 to 6.

Wherein the pH adjuster is a basic salt.

Wherein the etching inhibitor is a C1-C10 heterocyclic compound. The hetero atoms contained in the heterocyclic compound are 0 or N.

Wherein the chelating agent is a compound containing amino group and carboxyl group. The chelating agent is iminodiacetic acid, ethylenediaminetetraacetic acid, or ethylenediamine tetramethylene phosphoric acid.

Wherein the etching additive is a phosphate. The phosphate is monoammonium phosphate, triammonium phosphate, or disodium hydrogen phosphate.

### Embodiment 4

Compared with the embodiment 3, embodiment 4 is different only in: no glycol is added to the etchant composition in Embodiment 4.

### Embodiment 5

The present embodiment uses the etchant composition in the embodiment 1 to 3 in the etching of a metal wiring, wherein the metal wiring is a triple layer metal wiring structure of molybdenum/copper/molybdenum laminated layers or molybdenum alloy/copper/molybdenum alloy laminated layers.

In the triple layer metal wiring, the thickness of a first layer ranges from 50 Å to 500 Å, a thickness of a middle copper electrode second layer ranges from 3000 Å to 10000 Å, and a thickness of a third layer ranges from 50 Å to 300 Å.

### Embodiment 6

The present embodiment provides a method of manufacturing a thin film array substrate, wherein the method comprises steps of:

forming a gate electrode having two layers of metal structures on a substrate;

forming a gate electrode insulating layer on the gate electrode;

forming an active layer of oxide semiconductor on the gate electrode insulating layer;

forming a source electrode and a drain electrode on the active layer, wherein each of the source electrode and the drain electrode is a triple layer metal structure, wherein the triple layer metal structure is molybdenum/copper/molybdenum laminated layers or molybdenum alloy/copper/molybdenum alloy laminated layers, wherein a thickness of a lowermost layer (first layer) ranges from 50 Å to 500 Å, a thickness of a middle copper electrode (second layer) ranges from 3000 Å to 10000 Å, and a thickness of an uppermost layer (third layer) ranges from 50 Å to 300 Å; and

wet-etching the source electrode and the drain electrode at a same time using the etchant composition of the embodiment 1 to 4 of the present disclosure.

Test Results:

In the present embodiment, when etching with the etchant composition of the embodiment 4, hydrogen peroxide is unstable, and the concentration of the hydrogen peroxide drops fast, causing a short life span (about 2000 ppm) of the etchant.

In the present embodiment, when etching with the etchant composition of the embodiment 1 to 3, hydrogen peroxide is stable, and the life span of the etchant is extended to 3000-4000 ppm.

It can be seen by comparison that the etchant composition of the present disclosure not only slows down the degradation of the hydrogen peroxide but also extends the lifespan of the etchant, thereby greatly reducing the costs of the etchant in the manufacturing process, and improving the safety factor of the etchant.

It should be understood that equivalent substitutions and modifications can be made in accordance with the technical solutions and inventive concepts of the present disclosure for a person of ordinary skill in the art. All such modifications and substitutions should belong to the scopes of the claims appended in the present invention.

What is claimed is:

1. An etchant composition for etching a triple layer metal wiring structure of molybdenum/copper/molybdenum or molybdenum alloy/copper/molybdenum alloy, wherein the etchant composition comprises: hydrogen peroxide, glycol, an etching inhibitor, a chelating agent, an etching additive, a pH adjuster, and water;
wherein the glycol is at least one selected from ethylene glycol, propylene glycol, diethylene glycol, propane-1,2-diol, triethylene glycol, 1,2-propanediol, 1,3-propanediol, 1,4-butanediol, 1,5-pentanediol, 1,6-hexanediol, 1,7-heptandiol, 1,8-octanediol, 1,9-nonanediol, 1,10-decanediol, cyclopentane-1,2-diol, and cyclohexane-1,4-diol.

2. The etchant composition as claimed in claim 1, wherein the etchant composition comprises: 20-30 wt % of hydrogen peroxide, 0.1-10 wt % of glycol, 0.1-5 wt % of the etching inhibitor, 0.1-5 wt % of the chelating agent, 0.1-5 wt % of the etching additive, 0.1-3 wt % of the pH adjuster, and the remainder being water.

3. The etchant composition as claimed in claim 1, wherein a pH value of the etchant composition ranges from 2 to 6.

4. The etchant composition as claimed in claim 2, wherein a pH value of the etchant composition ranges from 2 to 6.

5. The etchant composition as claimed in claim 2, wherein the etchant composition comprises: 23-27 wt % of hydrogen peroxide, 2-8 wt % of glycol, 1-3 wt % of the etching inhibitor, 1-4 wt % of the chelating agent, 1-3 wt % of the etching additive, 0.8-2 wt % of the pH adjuster, and the remainder being water.

6. The etchant composition as claimed in claim 1, wherein a pH value of the etchant composition ranges from 3 to 6.

7. The etchant composition as claimed in claim 3, wherein the pH adjuster is at least one selected from organic bases, inorganic bases, and basic salts.

8. The etchant composition as claimed in claim 1, wherein the etching inhibitor is a C1-C10 heterocyclic compound.

9. The etchant composition as claimed in claim 8, wherein the hetero atoms contained in the heterocyclic compound are at least one selected from O, S, and N.

10. The etchant composition as claimed in claim 1, wherein the chelating agent is a compound containing amino group and carboxyl group.

11. The etchant composition as claimed in claim 10, wherein the chelating agent is at least one selected from iminodiacetic acid, nitrilotriacetic acid, ethylenediaminetetraacetic acid, diethylenetriaminepentaacetic acid, nitrilotrimethylene triphosphonic acid, 1-hydroxyethylene-1,1-diphosphoric acid, ethylenediamine tetramethylene phosphoric acid, and diethylenetriamine penta(methylene phosphonic acid).

12. The etchant composition as claimed in claim 1, wherein the etching additive is at least one selected from organic acids, inorganic acids, and phosphates.

13. The etchant composition as claimed in claim 12, wherein the phosphate is at least one selected from monoammonium phosphate, diammonium phosphate, triammonium phosphate, sodium hydrogen phosphate, disodium hydrogen phosphate, sodium phosphate, potassium hydrogen phosphate, dipotassium hydrogen phosphate, and potassium phosphate.

14. A use of the etchant composition as claimed in claim 1 in etching of a metal wiring structure, wherein the metal wiring structure is a triple layer metal wiring structure of molybdenum/copper/molybdenum laminated layers or molybdenum alloy/copper/molybdenum alloy laminated layers.

15. The use as claimed in claim 14, wherein in the metal wiring structure, a thickness of a lowermost layer ranges from 50 Å to 500 Å, a thickness of a middle copper electrode ranges from 3000 Å to 10000 Å, and a thickness of an uppermost layer ranges from 50 Å to 300 Å.

16. The use as claimed in claim 14, wherein the etchant composition comprises: 20-30 wt % of hydrogen peroxide, 0.1-10 wt % of glycol, 0.1-5 wt % of an etching inhibitor, 0.1-5 wt % of a chelating agent, 0.1-5 wt % of an etching additive, 0.1-3 wt % of a pH adjuster, and the remainder being water.

17. The use as claimed in claim 14, wherein a pH value of the etchant composition ranges from 2 to 6.

18. The use as claimed in claim 14, wherein the pH adjuster is at least one selected from organic bases, inorganic bases, and basic salts; the etching inhibitor is a C1-C10 heterocyclic compound; the hetero atoms contained in the heterocyclic compound are at least one of O, S, or N; the chelating agent is a compound containing amino group and carboxyl group; and the etching additive is at least one selected from organic acids, inorganic acids, and phosphates.

19. A method of manufacturing a thin film array substrate using the etchant composition claimed in claim 1, wherein the method comprises steps of:
forming a gate electrode having two layers of metal structures on a substrate;
forming a gate electrode insulating layer on the gate electrode;
forming an active layer of oxide semiconductor on the gate electrode insulating layer;
forming a source electrode and a drain electrode on the active layer, wherein each of the source electrode and the drain electrode is a triple layer metal structure, wherein the triple layer metal structure is molybdenum/copper/molybdenum laminated layers or molybdenum alloy/copper/molybdenum alloy laminated layers, wherein a thickness of a lowermost layer ranges from 50 Å to 500 Å, a thickness of a middle copper electrode ranges from 3000 Å to 10000 Å, and a thickness of an upper most layer ranges from 50 Å to 300 Å; and
wet etching the source electrode and the drain electrode at a same time using the etchant composition.

20. The method as claimed in claim 19, wherein the etchant composition comprises: 20-30 wt % of hydrogen peroxide, 0.1-10 wt % of glycol, 0.1-5 wt % of an etching inhibitor, 0.1-5 wt % of a chelating agent, 0.1-5 wt % of an etching additive, 0.1-3 wt % of a pH adjuster, and the remainder being water; and a pH value of the etchant composition ranges from 2 to 6; and
wherein the pH adjuster is at least one selected from organic bases, inorganic bases, and basic salts; the etching inhibitor is a C1-C10 heterocyclic compound; the hetero atoms contained in the heterocyclic compound are at least one of O, S, or N; the chelating agent is a compound containing amino group and carboxyl group; and the etching additive is at least one selected from organic acids, inorganic acids, and phosphates.
